(19) United States
(12) Patent Application Publication
(10) Pub. No.: US 2014/0054545 A1
(43) Pub. Date: Feb. 27, 2014

(54) PHOTODETECTOR, EPITAXIAL WAFER AND METHOD FOR PRODUCING THE SAME

(71) Applicant: Sumitomo Electric Industries, Ltd., Osaka-shi (JP)

(72) Inventors: Katsushi Akita, Itami-shi (JP); Kei Fujii, Itami-shi (JP); Takashi Ishizuka, Itami-shi (JP); Youichi Nagai, Osaka-shi (JP)

(73) Assignee: Sumitomo Electric Industries, Ltd., Osaka-shi (JP)

(21) Appl. No.: 14/115,074

(22) PCT Filed: Oct. 29, 2012
(86) PCT No.: PCT/JP2012/077889

§ 371 Date: Oct. 31, 2013

(30) Foreign Application Priority Data
Nov. 1, 2011 (JP) 2011-240396

(51) Int. Cl. H01L 31/105; H01L 31/0352; H01L 31/18

(52) U.S. Cl. CPC H01L 31/105; H01L 31/1844; H01L 31/035236
USPC 257/21; 438/87

(57) ABSTRACT

Provided are a photodetector in which, in a III-V semiconductor having sensitivity in the near-infrared region to the far-infrared region, the carrier concentration can be controlled with high accuracy; an epitaxial wafer serving as a material of the photodetector; and a method for producing the epitaxial wafer. Included are a substrate formed of a III-V compound semiconductor; an absorption layer configured to absorb light; a window layer having a larger bandgap energy than the absorption layer; and a p-n junction positioned at least in the absorption layer, wherein the window layer has a surface having a root-mean-square surface roughness of 10 nm or more and 40 nm or less.

### TECHNICAL FIELD

The present invention relates to a photodetector, an epitaxial wafer, and a method for producing the epitaxial wafer. Specifically, the present invention relates to a photodetector including, as an absorption layer, a multiple-quantum well structure (MQW) containing a III-V compound semiconductor and having sensitivity in the near-infrared region to the far-infrared region; an epitaxial wafer; and a method for producing the epitaxial wafer.

### BACKGROUND ART

InP-based semiconductors, which are III-V compounds, have a bandgap energy corresponding to the near-infrared region and hence a large number of studies are performed for developing photodetectors for communications, image capturing at night, and the like. For example, Non Patent Literature 1 proposes a photodetector in which an InGaAs/GaAsSb type-II MQW is formed on an InP substrate and a p-n junction is formed with a p-type or n-type epitaxial layer to achieve a cutoff wavelength of 2.39 μm, the photodetector having characteristic sensitivity in a wavelength range of 1.7 μm to 2.7 μm. In addition, Non Patent Literature 2 describes a photodetector having a type-II MQW absorption layer having 150 pairs layered such that 5 nm InGaAs and 5 nm GaAsSb constitute a single pair, the photodetector having characteristic sensitivity (200 K, 250 K, and 295 K) in a wavelength range of 1 μm to 3 μm.

In addition, Patent Literature 1 proposes the following technique: in a light receiving element that includes an absorption layer containing antimony (Sb) as a group V element and an InP window layer, the InP window layer is formed so as to contain a donor impurity; as a result, entry of antimony into the InP window layer causing conversion into a p-type window layer is canceled out to thereby decrease the dark current.

### CITATION LIST

### Non Patent Literature

NPL 1: R. Sidhu, et. al. “A Long-Wavelength Photodiode on InP Using Lattice-Matched GaInAs—GaAsSb Type-II Quantum Wells”, IEEE Photonics Technology Letters, Vol. 17, No. 12 (2005), pp. 2715-2717
NPL 2: R. Sidhu, et. al. “A 2.3 μm Cutoff Wavelength Photodiode on InP Using Lattice-Matched GaInAs—GaAsSb Type-II Quantum Wells”, 2005 International Conference on Indium Phosphide and Related Materials, pp. 148-151

### Patent Literature

PTL 1: Japanese Unexamined Patent Application Publication No. 2011-60853

### SUMMARY OF INVENTION

### Technical Problem

However, the photodetector having a cutoff wavelength of 2.39 μm in NPL 1 has a high dark current, which is probably caused by use of an InGaAs layer as a window layer and formation of an electrode and a passivation film on this InGaAs layer. That is, compared with the case of using an InP layer as a window layer, use of a window layer formed of InGaAs results in a high dark current. Use of a window layer formed of InP provides, in addition to the advantage relating to dark current, another advantage. Specifically, when an InP window layer is used such that light is introduced through the window layer, another advantage of low absorption in the near-infrared region is also provided.

On the other hand, in PTL 1, when a p-type impurity is selectively diffused through the InP window layer, a high dark current may be caused depending on conditions. After formation of an epitaxial layer containing antimony, in the growth chamber, depending on formation conditions, the incorporation efficiency of antimony or the density of acceptor-type defects is increased by an unknown mechanism. As a result, the InP window layer has such an acceptor concentration that is not canceled out by addition of a donor impurity. This high acceptor concentration causes formation of p-n junctions in regions other than the anode region that is selectively formed. Accordingly, for example, the increase in the area of p-n junctions causes an increase in the dark current.

In addition, an increase in the acceptor concentration beyond the intended level causes formation of unintended semiconductor elements. As a result, the sensitivity is also considerably degraded.

An object of the present invention is to provide a photodetector in which the carrier concentration can be controlled with high accuracy in a III-V compound semiconductor having sensitivity in the near-infrared region to the far-infrared region; an epitaxial wafer serving as a material of the photodetector; and a method for producing the epitaxial wafer. By achieving the control of the carrier concentration with high accuracy, high sensitivity and low dark current can be achieved.

### Solution to Problem

A photodetector according to the present invention includes a substrate formed of a III-V compound semiconductor; an absorption layer that is positioned on the substrate and configured to absorb light; a window layer that is positioned on the absorption layer and has a larger bandgap energy than the absorption layer; and a p-n junction positioned at least in the absorption layer, wherein the window layer has a surface having a root-mean-square (RMS) surface roughness of 10 nm or more and 40 nm or less.

Here, the RMS value of existing photodetectors is less than 10 nm, mostly, for example, about 7 nm to about 8 nm. In the present invention, the RMS value needs to be in the range of 10 nm or more and 40 nm or less. That is, compared with the existing level, higher roughness needs to be provided. Although the reason for this will be described in detail below, when the RMS value is less than 10 nm, the window layer tends to be formed as a p-type layer. Stated another way, the acceptor concentration of the window layer is increased. As a result, it becomes difficult to control the carrier concentration with high accuracy and production of photodetectors having high sensitivity and low dark current cannot be performed with stability.

Note that, when the RMS value is increased to 10 nm or more, the acceptor concentration of the window layer does not increase. This is probably because the density of acceptor-type impurity elements and point defects in the window layer does not increase. That is, when the RMS value is less than 10 nm, the density of acceptor-type impurity elements and point defects in the window layer increases and the acceptor concentration is increased. In addition, a large number of experiments have indicated that, when a p-type impurity material is incorporated into the window layer such that the p-type impurity material functions as an acceptor in the semiconductor, the window layer has an RMS value of less than 10 nm (that is, smooth layer) and it becomes difficult to control the carrier concentration with high accuracy. When the RMS value is 10 nm or more, the acceptor concentration does not increase.

Thus, by performing impurity control in accordance with the predetermined procedure, the control of carrier concentration can be achieved with high accuracy. As described below, the above-described feature is easily achieved by satisfying a predetermined condition in terms of the orientation of the substrate.

On the other hand, when the RMS value is more than 40 nm, as known in the usual cases of poor flatness, for example, it becomes difficult to form electrodes. Accordingly, a photodetector having high sensitivity and low dark current cannot also be obtained.

When the RMS value is 10 nm or more and 40 nm or less, this flatness is not good at all in the standard sense. However, this flatness is not so poor that electrodes, a passivation film, and the like cannot be formed; and electrodes and a passivation film can be formed without great difficulties.

The present invention is unique in that it has revealed the following: in the cases of a good or standard flatness (an RMS value of less than 10 nm), it is less likely to achieve impurity control with high accuracy. As described above, when the flatness is excessively poor (an RMS value of more than 40 nm), a photodetector having high sensitivity and low dark current cannot be obtained, which is well known.

RMS values may be measured by any instrument. For example, a commercially available atomic force microscopy (AFM) may be employed and the RMS measurement is selected to obtain data (average value). In this measurement, the measurement range (length and width, area, or the like) is not particularly limited and any range may be employed; for example, an RMS average is preferably determined in a measurement range such as a gap region between a pixel electrode and a selective diffusion mask pattern, a square region having 10 μm sides, or a square region having 100 μm sides.

In a photodetector according to the present invention, the p-n junction may be formed by selective diffusion of an impurity through the window layer.

In this case, a photodetector unit that is independent from the surroundings can be obtained. That is, in the case of a single photodetector, the influence of the peripheral edge can be reduced; and, in the case of a plurality of photodetectors that are one- or two-dimensionally arranged, independence from the neighboring photodetectors can be ensured.

However, in the case of a p-type pixel region, when the acceptor concentration of the window layer increases, the area of the p-n junction is expanded even to a region other than the pixel region selectively formed. As a result, the dark current is increased. In addition, the sensitivity is also adversely affected. The p-type impurity introduced into a pixel region is often zinc (Zn).

On the other hand, even in the case of an n-type pixel region, the concentration of a p-type impurity (acceptor impurity) increases and an excessively large amount of a donor impurity is necessary. Thus, the crystallinity is degraded, which also results in an increase in the dark current and a decrease in the sensitivity. Hereinafter, the case where a pixel region is a p-type region will be mainly described.

In a photodetector according to the present invention, the substrate preferably has an off angle of −0.05° or more and +0.05° or less with respect to a (001) plane serving as a main surface of the substrate.

By using such a substrate having an off angle of −0.05° or more and +0.05° or less with respect to a (001) plane (hereafter, referred to as a just-angle substrate), the above-described RMS-value range is easily achieved; in particular, an RMS value of 10 nm or more is easily achieved. In general, in the production of a photodetector containing a III-V compound semiconductor, not a just-angle substrate but an off-angle substrate (0.05° to 0.1° off a (001) plane) is used. This is because, in consideration of, for example, off-angle surface energy, thermodynamically, the epitaxial growth of a layer on the surface is easily achieved. In the present invention, when an off-angle substrate on which epitaxial growth tends to proceed is used, incorporation of a p-type impurity tends to be caused and the p-type impurity functions as an acceptor in the semiconductor. When a just-angle substrate on which epitaxial growth is less likely to proceed is used, as a result, the above-described RMS-value range is easily achieved.

Note that a substrate having an off angle of ±0.05° with respect to a (001) plane may be classified as a just-angle substrate or an off-angle substrate. However, in the present invention, an off angle of ±0.05° is understood as an error with respect to the central value, which is 0°. In general, when an off-angle substrate is specified and it has an off angle of ±0.05°, it is understood that the central value of the off angle is ±0.05°.

In a photodetector according to the present invention, the window layer may contain phosphorus (P).

When the window layer is formed of a compound semiconductor containing P and the RMS value is not in the above-described range, the window layer tends to be formed as a p-type layer. When a compound semiconductor containing P is used to form the window layer, the P-containing material itself or a material containing a p-type impurity tends to enter the window layer during epitaxial growth. Even when such a material enters the window layer, as long as the RMS value is in the above-described range (10 nm or more and 40 nm or less), the carrier concentration (acceptor concentration) in the semiconductor is in the intended proper range. Accordingly, as described above, for example, in the case of growing an InP window layer, which has a large number of great advantages that cannot be provided by other compound semiconductors, advantages of the present invention are provided to thereby allow high usefulness.

In a photodetector according to the present invention, the absorption layer may include a III-V compound semiconductor layer containing antimony (Sb).

Sb tends to be distributed in the surface and causes, in the surface layer, a large number of adverse effects such as an increase in the density of acceptor-type defects. By satisfying the RMS-value range in the present invention, the adverse effects peculiar to antimony can be reduced. Stated another way, when the absorption layer contains antimony, employment of the present invention can very effectively reduce the adverse effects due to antimony to thereby provide a photodetector having high quality.

In a photodetector according to the present invention, the window layer may contain antimony (Sb) as an impurity element.

When the window layer contains Sb as an impurity and the RMS value is not in the above-described range, the window layer tends to be formed as a p-type layer. There has been a trend toward common use of Sb in the absorption layers of near-infrared photodetectors. Accordingly, in the case of using Sb, by adjusting the RMS value to be in the above-described range, the carrier concentration can be controlled with high accuracy and a near-infrared photodetector having high sensitivity and low dark current can be provided.

In a photodetector according to the present invention, the absorption layer may have a multiple-quantum well structure constituted by a pair of InₓGa₁₋ₓAs (0.38≦x≦1.00) and GaAs_{1-y}Sb_{y} (0.36≦y≦1.00) or a pair of Ga₁₋ᵤInᵤNᵥAs₁₋ᵥ (0.4≦u≦1.0, 0<v≦0.2) and GaAs_{1-w}Sb_{w} (0.36≦w≦1.00).

By forming the absorption layer so as to have this multiple-quantum well structure (MQW), absorption of light having a wavelength of 2 μm to 10 μm in the near-infrared region to the far-infrared region can be achieved with high sensitivity and low dark current. Since the MQW contains Sb, it is important that the above-described features in terms of the RMS value and the like are satisfied.

In a photodetector according to the present invention, the substrate may be formed of any one of GaAs, GaP, GaSb, InP, InAs, InSb, AlSb, and AlAs.

Selection of the substrate in terms of these materials enhances the freedom of choice for obtaining, for example, a photodetector that is suitable for a predetermined wavelength range in the near-infrared region to the far-infrared region.

A photodetector according to the present invention may include a diffusive-concentration-distribution-adjusting layer that is formed of a III-V compound semiconductor and is in contact with a surface of the absorption layer, the surface being on a side opposite to the substrate.

In this case, the impurity concentration in the absorption layer can be controlled to be relatively low with high accuracy. As a result, the absorption layer can be formed so as to have high crystallinity.

In a photodetector according to the present invention, the absorption layer preferably contains InₓGa₁₋ₓAs (0.38≦x≦1.00), the diffusive-concentration-distribution-adjusting layer preferably contains In_{z}Ga_{1-z}As (0.38≦z≦1.00), and a total film thickness of the InₓGa₁₋ₓAs and the In_{z}Ga_{1-z}As is preferably 2.3 μm or more.

By adjusting the total film thickness to be 2.3 μm or more, high sensitivity and low dark current can be achieved.

An epitaxial wafer according to the present invention includes a substrate formed of a III-V compound semiconductor; an absorption layer that is positioned on the substrate and configured to absorb light; and a window layer that is positioned on the absorption layer and has a larger bandgap energy than the absorption layer, wherein the window layer has a surface having a root-mean-square (RMS) surface roughness of 10 nm or more and 40 nm or less.

As described above, when the RMS value is less than 10 nm, the window layer tends to be formed as a p-type layer. As a result, it becomes difficult to control the impurity concentration with high accuracy and production of photodetectors having high sensitivity and low dark current cannot be performed with stability. When the RMS value is more than 40 nm, the flatness is poor in the standard sense and it becomes difficult to produce a non-defective photodetector.

An epitaxial wafer according to the present invention may include a p-n junction positioned at least in the absorption layer.

In this case, an epitaxial wafer for producing a photodetector in which the impurity is controlled with high accuracy can be provided.

An epitaxial wafer according to the present invention may include a p-n junction formed by selective diffusion of an impurity through the window layer.

In this case, an epitaxial wafer in which the impurity is controlled with high accuracy can be provided for producing a planar photodetector.

In an epitaxial wafer according to the present invention, the substrate preferably has an off angle of −0.05° or more and +0.05° or less with respect to a (001) plane serving as a main surface of the substrate.

As a result of using such a just-angle substrate, the above-described RMS-value range is easily achieved and the acceptor concentration can be controlled with high accuracy.

In an epitaxial wafer according to the present invention, the window layer may contain phosphorus (P).

When a compound semiconductor containing P is used to form the window layer, the P-containing material itself or a material containing a p-type impurity tends to enter the window layer during epitaxial growth. However, as long as the RMS value is in the above-described range (10 nm or more and 40 nm or less), the carrier concentration (acceptor concentration) in the semiconductor is in the intended proper range.

In an epitaxial wafer according to the present invention, the absorption layer may include a III-V compound semiconductor layer containing antimony (Sb).

Sb causes, in the surface layer, a large number of adverse effects such as an increase in the density of acceptor-type defects. By satisfying the RMS-value range in the present invention, the adverse effects peculiar to antimony can be reduced.

In an epitaxial wafer according to the present invention, the window layer may contain antimony (Sb) as an impurity element.

When the window layer contains Sb as an impurity and the RMS value is not in the above-described range, the window layer tends to be formed as a p-type layer. Accordingly, in the case of using Sb, by adjusting the RMS value to be in the above-described range, the carrier concentration can be controlled with high accuracy and a near-infrared photodetector having high sensitivity and low dark current can be provided.

In an epitaxial wafer according to the present invention, the absorption layer may have a multiple-quantum well structure constituted by a pair of InₓGa₁₋ₓAs (0.38≦x≦1.00) and GaAs_{1-y}Sb_{y} (0.36≦y≦1.00) or a pair of Ga₁₋ᵤInᵤNᵥAs₁₋ᵥ (0.4≦u≦1.0, 0<v≦0.2) and GaAs_{1-w}Sb_{w} (0.36≦w≦1.00).

By forming the absorption layer so as to have this MQW, absorption of light having a wavelength of 2 μm to 10 μm in the near-infrared region to the far-infrared region can be achieved with high sensitivity and low dark current. Although the MQW contains Sb, by satisfying the above-described features in terms of the RMS value and the like according to the present invention, a photodetector having high quality can be provided.

In an epitaxial wafer according to the present invention, the substrate may be formed of any one of GaAs, GaP, GaSb, InP, InAs, InSb, AlSb, and AlAs.

Selection of the substrate in terms of these materials enhances the freedom of choice in the near-infrared region to the far-infrared region.

An epitaxial wafer according to the present invention may include a diffusive-concentration-distribution-adjusting layer that is formed of a III-V compound semiconductor and is in contact with a surface of the absorption layer, the surface being on a side opposite to the substrate.

In this case, the impurity concentration in the absorption layer can be controlled to be relatively low with high accuracy. As a result, the absorption layer can be formed so as to have high crystallinity.

In an epitaxial wafer according to the present invention, the absorption layer preferably contains InₓGa₁₋ₓAs (0.38≦x≦1.00), the diffusive-concentration-distribution-adjusting layer preferably contains In_{z}Ga_{1-z}As (0.38≦z≦1.00), and a total film thickness of the InₓGa₁₋ₓAs and the In_{z}Ga_{1-z}As is preferably 2.3 μm or more.

By adjusting the total film thickness to be 2.3 μm or more, high sensitivity and low dark current can be achieved.

A method for producing an epitaxial wafer according to the present invention includes growing, by metal-organic vapor phase epitaxy using only metal-organic sources, at least the absorption layer and the window layer of the above-described epitaxial wafer.

Here, metal-organic vapor phase epitaxy using only metal-organic sources denotes epitaxy in which only metal-organic sources composed of metal-organic compounds are used as the sources used for the vapor phase epitaxy. By employing metal-organic vapor phase epitaxy using only metal-organic sources, an epitaxial wafer having high quality in terms of crystalline quality can be produced with high efficiency. In particular, when an epitaxial wafer having a window layer formed of a P-containing compound semiconductor is produced not by metal-organic vapor phase epitaxy using only metal-organic sources, a phosphorus compound derived from the phosphorus source adheres to the inner wall of the growth chamber. Accordingly, unless maintenance (cleaning or replacement) is performed with certainty, problems such as ignition are caused. However, in metal-organic vapor phase epitaxy using only metal-organic sources, since the source is a vapor phase organophosphorus compound, such problems are less likely to be caused.

In a method for producing an epitaxial wafer according to the present invention, a diffusive-concentration-distribution-adjusting layer is preferably grown on and in contact with the absorption layer such that a growth temperature of the diffusive-concentration-distribution-adjusting layer is equal to or lower than a growth temperature of the absorption layer.

In this case, the RMS value is easily adjusted to be in the range of 10 nm or more and 40 nm or less.

### Advantageous Effects of Invention

According to the present invention, the carrier concentration is controlled with high accuracy and, as a result, for example, a photodetector that has high sensitivity and low dark current and is used for the near-infrared region to the far-infrared region can be obtained.

### BRIEF DESCRIPTION OF DRAWINGS

FIG. 1 illustrates a photodetector according to an embodiment of the present invention.

FIG. 2 illustrates a feature (point) of the photodetector in FIG. 1.

FIG. 3 illustrates an epitaxial wafer according to an embodiment of the present invention.

FIG. 4 is a flow chart of a production method.

FIG. 5 illustrates the piping system and the like of a deposition apparatus for metal-organic vapor phase epitaxy using only metal-organic sources.

FIG. 6A illustrates flow of metal-organic molecules and thermal flow.

FIG. 6B is a schematic view of metal-organic molecules on a substrate surface.

FIG. 7 is a flow chart of a latter part of a method for producing a photodetector illustrated in FIG. 1.

FIG. 8 illustrates a photodetector according to another embodiment of the present invention.

### REFERENCE SIGNS LIST

1: InP substrate, 1a: epitaxial wafer, 2: InP buffer layer, 3: MQW absorption layer, 4: InGaAs layer (diffusive-concentration-distribution-adjusting layer), 5: InP window layer, 6: p-type region, 7: epitaxial layers (epitaxial layer structure) formed by metal-organic vapor phase epitaxy using only metal-organic sources, 10: photodetector, 11: p-electrode (pixel electrode), 12: ground electrode (n-electrode), 15: p-n junction, 16: interface between MQW and InGaAs layer, 17: interface between InGaAs layer and InP window layer, 35: anti-reflection (AR) film, 36: selective diffusion mask pattern, 60: deposition apparatus for metal-organic vapor phase epitaxy using only metal-organic sources, 61: infrared thermometer, 63: reaction chamber, 65: quartz tube, 66: substrate table, 66h: heater, 69: window of reaction chamber, 70: atomic force microscopy (AFM), 71: cantilever, 72: cantilever holder, 73: probe, 75: laser beam

### DESCRIPTION OF EMBODIMENTS

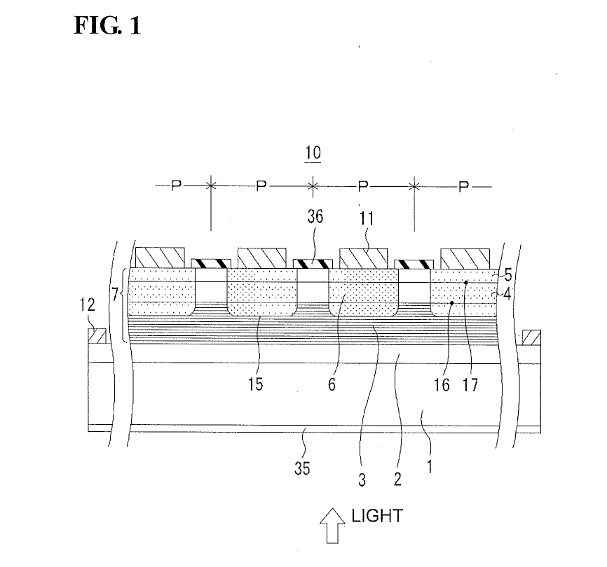

FIG. 1 is a sectional view illustrating a photodetector 10 according to a first embodiment of the present invention. FIG. 1 indicates that the photodetector 10 has, on an InP substrate 1, a III-V compound semiconductor layer structure having the following configuration:

(InP substrate 1/InP buffer layer 2/absorption layer 3 having multiple-quantum well structure (MQW) of In_{0.59}Ga_{0.41}As and GaAs_{0.57}Sb_{0.43}/InGaAs diffusive-concentration-distribution-adjusting layer 4/InP window layer 5)

Among the above-described layers, at least an epitaxial layer structure 7 constituted by absorption layer 3/InGaAs diffusive-concentration-distribution-adjusting layer 4/InP window layer 5 is preferably formed by metal-organic vapor phase epitaxy using only metal-organic sources.

A p-type region 6 is positioned from the InP window layer 5 to the absorption layer 3 having a multiple-quantum well structure. Such p-type regions 6 are formed by selective diffusion of Zn serving as a p-type impurity through openings of a selective diffusion mask pattern 36 of a SiN film. Each p-type region 6 is isolated from its neighboring p-type regions 6 by regions that are not subjected to the selective diffusion. As a result, each of pixels P can independently output absorption data.

In the p-type regions 6, p-electrodes 11 composed of AuZn are disposed so as to form ohmic contacts with the p-type regions 6. On exposed end portions of the surface of the buffer layer 2, which is disposed so as to be in contact with the InP substrate 1, n-electrodes 12 composed of AuGeNi are disposed so as to form ohmic contacts with the exposed end portions. The buffer layer 2 is doped with an n-type impurity so as to have a predetermined level of conductivity. In this case, the InP substrate 1 may be an n-type conductive or semi-insulating substrate.

Light enters the InP substrate 1 through the back surface thereof. In order to suppress reflection of incident light, an AR (anti-reflection) film 35 formed of SiON or the like covers the back surface of the InP substrate 1.

A p-n junction 15 is formed at a position corresponding to the boundary front of the p-type region 6. By applying a reverse bias voltage between the p-electrode 11 and the n-electrode 12, in the absorption layer 3, a depletion layer is formed in a larger area on a side in which the concentration of the n-type impurity is lower (n-type impurity background concentration). The background impurity concentration in the absorption layer 3 having a multiple-quantum well structure is, in terms of n-type impurity concentration (carrier concentration), about 1×10¹⁶ cm⁻³ or less. The position of the p-n junction is determined from the point of intersection of the background impurity concentration (n-type carrier concentration) and the concentration profile of p-type impurity Zn in the absorption layer 3 having a multiple-quantum well.

In the diffusive-concentration-distribution-adjusting layer 4, the concentration of the p-type impurity selectively diffused through the surface of the InP window layer 5 sharply drops from the high-concentration region on the InP-window-layer side to the absorption-layer side. Accordingly, in the absorption layer 3, an impurity concentration, that is, a Zn concentration of 5×10¹⁶ cm⁻³ or less can be easily achieved.

A photodetector 10 according to the present invention is intended to have sensitivity from the near-infrared region to the longer wavelength range. Accordingly, the window layer is preferably formed of a material having a bandgap energy larger than the bandgap energy of the absorption layer 3. For this reason, the window layer is generally formed of InP, which is a material that has a larger bandgap energy than the absorption layer and is highly lattice-matched. Alternatively, InAlAs, which has substantially the same bandgap energy as InP, may be used.

### (Points in the Present Embodiment)

Features in the present embodiment lie in the following points.

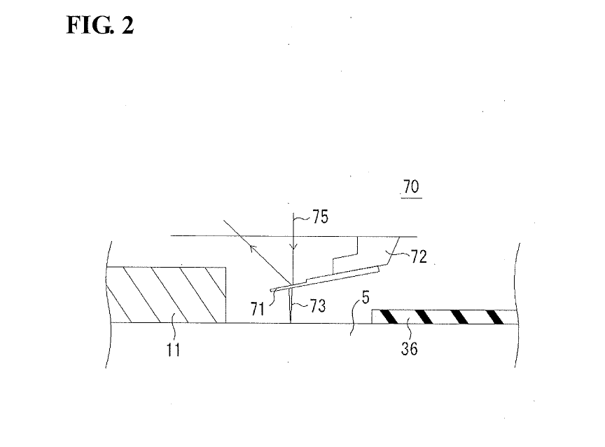

(1) The InP window layer 5 has a surface having an RMS value of 10 nm or more and 40 nm or less. FIG. 2 is a schematic view illustrating the surface of the InP window layer 5 of the photodetector 10 in FIG. 1, the surface being measured with an atomic force microscopy (AFM) 70. In the AFM 70, a probe 73 is attached to the tip of a cantilever 71, which is held by a cantilever holder 72; the tilt of the cantilever 71 is sharply changed in accordance with irregularities of the sample surface. This change in the tilt of the cantilever 71 is detected with a laser beam 75 to thereby obtain the data of the sample surface in terms of irregularities on the nanometer order. The irregularities of the sample surface, which is the surface of the InP window layer 5, are measured, calculated as an RMS value, and automatically indicated on the apparatus. This RMS value needs to be 10 nm or more and 40 nm or less in the present invention.

A large number of experiments have indicated that, when a p-type impurity material is incorporated into the window layer such that the p-type impurity material functions as an acceptor in the semiconductor, the window layer has an RMS value of less than 10 nm (that is, smooth layer) and it becomes difficult to control the carrier concentration with high accuracy. When the RMS value is 10 nm or more, the acceptor concentration does not increase. Thus, by performing impurity control in accordance with the predetermined procedure, the control of carrier concentration can be achieved with high accuracy. On the other hand, when the RMS value is more than 40 nm, as known in the usual cases of poor flatness, for example, it becomes difficult to form electrodes. Accordingly, a photodetector having high sensitivity and low dark current cannot also be obtained.

When the RMS value is 10 nm or more and 40 nm or less, this flatness is out of the range of the flatness of existing photodetectors. However, this flatness is not so poor that electrodes, a passivation film, and the like cannot be formed. When the RMS value is in this range, electrodes and a passivation film can be formed without great difficulties.

The present invention is unique in that it has revealed the following: in the cases of a good or standard flatness (an RMS value of less than 10 nm), it is less likely to achieve the control of carrier concentration with high accuracy. As described above, when the flatness is excessively poor (an RMS value of more than 40 nm), a photodetector having high sensitivity and low dark current cannot be obtained, which is well known.

(2) Note that, in order to easily achieve the phenomenon in (1) above, the orientation of the substrate is important. Conventionally, an off-angle substrate has been used as a substrate composed of a III-V compound semiconductor. That is, a substrate has been used that has a plane orientation with an off angle of 0.05° to 0.1° with respect to the (001) plane. This is because, in consideration of, for example, off-angle surface energy and unavoidable surface defects, thermodynamically, the epitaxial growth of a layer on the surface is easily achieved.

However, in the present embodiment, not an off-angle substrate but a just-angle substrate is preferably used.

By using a just-angle substrate, 10 nm RMS value 40 nm is easily achieved. As a result, the control of carrier concentration with high accuracy is facilitated.

In the present embodiment, when a p-type impurity is incorporated from the atmosphere under a condition causing epitaxial growth to proceed (that is, an off-angle substrate), as described above, the p-type impurity in the material functions as an acceptor in the semiconductor. When a just-angle substrate on which epitaxial growth is less likely to proceed is used, the disadvantageous factor in the production is addressed and, as a result, the above-described RMS-value range is achieved.

Hereinafter, in the production of the photodetector 10 illustrated in FIG. 1 with a just-angle substrate, the RMS value of an epitaxial wafer used will be described. In the present embodiment, the surface of the InP window layer 5 does not have very good flatness: the average RMS value is 23.4 nm and the height difference (average value) is 90 nm. In such a case where the RMS value is 10 nm or more, a p-type impurity does not enter the InP window layer 5 so as to increase the acceptor concentration. Thus, the control of carrier concentration can be achieved with high accuracy. As a result, for example, the following problem can be avoided: the area of p-n junctions is increased to cause an increase in the leakage dark current.

In contrast, the surface of an epitaxial wafer used for producing an existing photodetector has a higher flatness than the surface of the counterpart of the present embodiment: the RMS value is 8.3 nm and the height difference is 30 nm. Obviously, compared with the existing epitaxial wafer, an epitaxial wafer in the present invention has the InP window layer 5 whose surface has a low flatness.

The test sample in the RMS-value measurement is an epitaxial wafer and the RMS value is an average value obtained by the measurement for a 100 μm×100 μm region of the epitaxial wafer. In the case of a photodetector, the surface of the InP window layer 5 is preferably measured in a gap between a pixel electrode and a selective diffusion mask pattern and the average value is calculated. Alternatively, for example, after the p-electrode 11 is removed by wet etching, for example, a 10 μm×10 μm region of the surface of the InP window layer 5 may be measured and the average value is calculated.

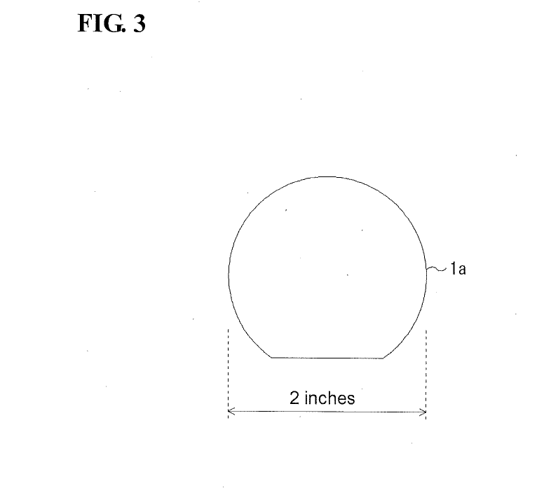

FIG. 3 illustrates an epitaxial wafer 1a in the present embodiment. The epitaxial wafer 1a in the present invention encompasses an epitaxial wafer in which the selective diffusion mask pattern is to be formed and the InP window layer 5 has been formed, and an epitaxial wafer in which the selective diffusion mask pattern 36 has been formed and selective diffusion of Zn or the like has been subsequently performed.

In the epitaxial wafer 1a in the present embodiment, the surface of the InP window layer 5 needs to have an RMS value of 10 nm or more and 40 nm or less. Such an RMS value allows the control of carrier concentration with high accuracy. Thus, an epitaxial wafer that allows production of a photodetector having high sensitivity and low dark current can be provided. As described above, this is easily achieved by using a just-angle substrate.

In FIG. 3, the epitaxial wafer 1a has a diameter of 2 inches and is a (001) just-angle substrate.

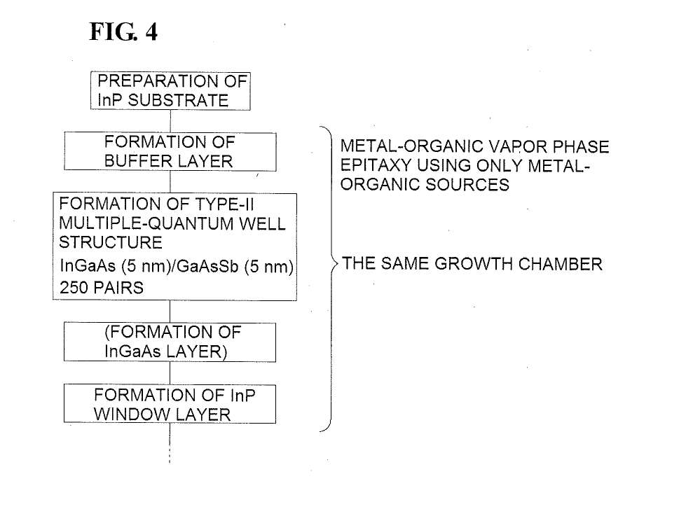

Hereinafter, the production method will be described with reference to FIG. 4. The InP substrate 1 is first prepared. On the InP substrate 1, the n-type InP buffer layer 2 is epitaxially grown so as to have a thickness of, for example, about 150 nm. The n-type doping is preferably performed with tetraethylsilane (TeESi). At this time, source gases used are trimethylindium (TMIn) and tertiarybutylphosphine (TBP). The InP buffer layer 2 may be grown with phosphine (PH₃), which is an inorganic material. Even when the InP buffer layer 2 is grown at a growth temperature of about 600° C. or about 600° C. or less, the crystallinity of the underlying InP substrate is not degraded by heating at about 600° C.

The layers overlying the buffer layer 2 are grown by metal-organic vapor phase epitaxy using only metal-organic sources, which can be performed at a low growth temperature and with high growth efficiency. It is evident that the InP buffer layer 2 may be grown by metal-organic vapor phase epitaxy using only metal-organic sources, which is a normal procedure. At least the type-II (InGaAs/GaAsSb) MQW 3, the InGaAs diffusive-concentration-distribution-adjusting layer 4, and the InP window layer 5 are continuously grown in the same growth chamber by metal-organic vapor phase epitaxy using only metal-organic sources. At this time, the growth temperature or the substrate temperature needs to be strictly kept within the temperature range of 400° C. or more and 550° C. or less. This is because, when a growth temperature higher than this temperature range is employed, GaAsSb is thermally damaged to undergo phase separation, resulting in an increase in the density of rough convex surface defects. Generation of such rough convex surface defects at a high density causes a considerable decrease in the production yield.

When a growth temperature of less than 400° C. is employed, the density of the convex surface defects decreases or becomes zero; however, source gases for metal-organic vapor phase epitaxy using only metal-organic sources are not sufficiently decomposed and carbon is incorporated into the epitaxial layer. The carbon is derived from the hydrocarbons bonded to the metals in the source gases. Incorporation of carbon into an epitaxial layer results in formation of an unintended p-type region and the resultant semiconductor elements have poor performance. For example, such photodetectors have a large dark current and cannot be practically used as products. Note that expansion of the p-type region due to incorporation of carbon is a phenomenon different from change in the carrier concentration relating to the RMS value, which is described above several times.

The method for producing an epitaxial wafer has been schematically described so far on the basis of FIG. 4. Hereinafter, growth methods of the layers will be described in detail.

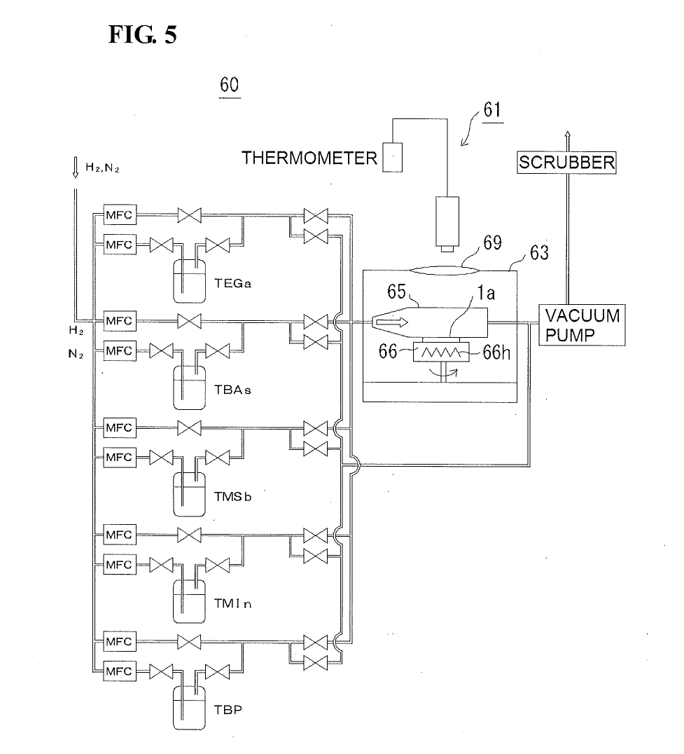

FIG. 5 illustrates the piping system and the like of a deposition apparatus 60 for metal-organic vapor phase epitaxy using only metal-organic sources. A quartz tube 65 is disposed in a reaction chamber (chamber) 63. Source gases are introduced into the quartz tube 65. In the quartz tube 65, a substrate table 66 is rotatably and hermetically disposed. The substrate table 66 is equipped with a heater 66h for heating a substrate. The surface temperature of the epitaxial wafer 1a during deposition is monitored with an infrared thermometer 61 through a window 69 disposed in the ceiling portion of the reaction chamber 63. This monitored temperature is referred to as, for example, the growth temperature, the deposition temperature, or the substrate temperature. Regarding formation of a MQW at a temperature of 400° C. or more and 550° C. or less in a production method according to the present invention, the temperature of 400° C. or more and 550° C. or less is a temperature measured in the temperature monitoring. Forced evacuation of the quartz tube 65 is performed with a vacuum pump.

Source gases are supplied through pipes connected to the quartz tube 65. Metal-organic vapor phase epitaxy using only metal-organic sources has a feature of supplying all the source gases in the form of metal-organic gases. That is, in the source gases, metals are bonded to various hydrocarbons. Although FIG. 5 does not describe source gases of, for example, impurities that govern the conductivity type, impurities are also introduced in the form of metal-organic gases. The metal-organic source gases are contained in constant temperature baths and kept at constant temperatures. The carrier gases used are hydrogen (H₂) and nitrogen (N₂). The metal-organic gases are carried with the carrier gases and sucked with the vacuum pump to thereby be introduced into the quartz tube 65. The flow rates of the carrier gases are accurately controlled with mass flow controllers (MFCs). A large number of mass flow controllers, electromagnetic valves, and the like are automatically controlled with microcomputers.

After the buffer layer 2 is grown, the absorption layer 3 having a type-II MQW is formed in which the quantum well is constituted by the pair of InGaAs/GaAsSb. In the quantum well, GaAsSb films have a thickness of, for example, 5 nm; and InGaAs films have a thickness of, for example, 5 nm. In the deposition of GaAsSb, triethylgallium (TEGa), tertiarybutylarsine (TBAs), and trimethylantimony (TMSb) are used. As for InGaAs, TEGa, TMIn, and TBAs can be used. These source gases are all metal-organic gases and the compounds have a high molecular weight. Accordingly, the gases can be completely decomposed at a relatively low temperature of 400° C. or more and 550° C. or less to contribute to crystal growth. The absorption layer 3 having a MQW can be formed by metal-organic vapor phase epitaxy using only metal-organic sources so as to have sharp composition changes at interfaces in the quantum well. As a result, spectrophotometry can be performed with high accuracy.

The Ga (gallium) source may be TEGa (triethylgallium) or trimethylgallium (TMGa). The In (indium) source may be TMIn (trimethylindium) or triethylindium (TEIn). The As (arsenic) source may be TBAs (tertiarybutylarsine) or trimethylarsenic (TMAs).

The Sb (antimony) source may be TMSb (trimethylantimony), triethylantimony (TESb), triisopropylantimony (TIPSb), or trisdimethylaminoantimony (TDMASb).

The source gases are carried through pipes, introduced into the quartz tube 65, and discharged. Any number of source gases may be supplied to the quartz tube 65 by increasing the number of pipes. For example, even more than ten source gases can be controlled by opening/closing of electromagnetic valves.

The flow rates of the source gases are controlled with mass flow controllers (MFCs) illustrated in FIG. 5 and introduction of the source gases into the quartz tube 65 is turned on/off by opening/closing of air-driven valves. The quartz tube 65 is forcibly evacuated with the vacuum pump. The source gases do not stagnate in anywhere and the flow rates thereof are smoothly automatically controlled. Accordingly, switching between compositions during the formation of the pair constituting the quantum well is quickly achieved.

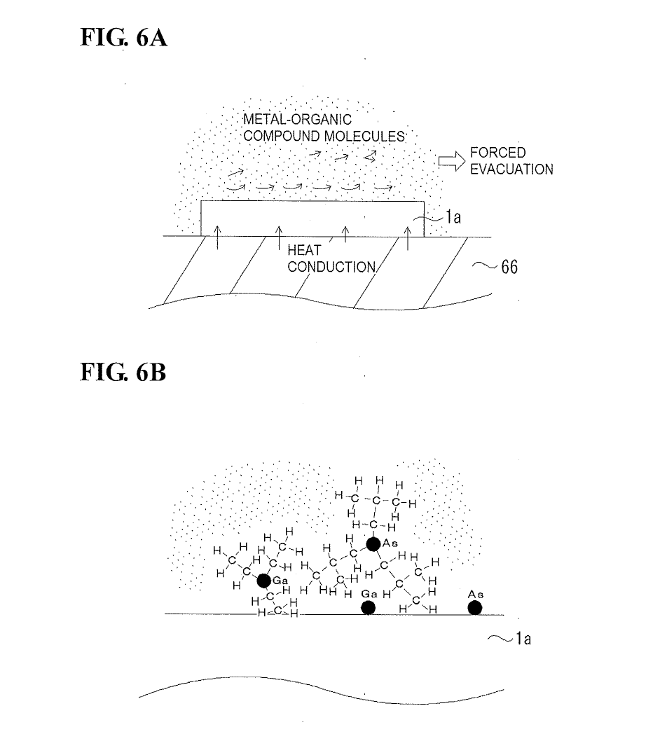

FIG. 6A illustrates flow of metal-organic molecules and thermal flow. FIG. 6B is a schematic view of metal-organic molecules on a substrate surface. The surface temperature of the epitaxial wafer 1a is monitored. The surface temperature is 400° C. or more and 550° C. or less. When metal-organic molecules having a large size illustrated in FIG. 6B flow over the wafer surface, compound molecules that decompose to contribute to crystal growth are probably limited to molecules in contact with the surface and molecules present within a thickness range extending for a length of several metal-organic molecules from the surface.

However, when the epitaxial wafer surface temperature or the substrate temperature is excessively low of less than 400° C., large molecules of source gases are not sufficiently decomposed: in particular, carbon is not sufficiently removed and is incorporated into the epitaxial wafer 1a. The carbon incorporated into III-V semiconductors serves as a p-type impurity and unintended semiconductor elements are formed. Thus, the intrinsic functions of the semiconductors are degraded, resulting in degradation of the performance of the produced semiconductor elements.

When source gases are selected with air-driven valves so as to correspond to the chemical compositions of the pair and introduced under forcible evacuation with a vacuum pump, after slight growth of a crystal having an old chemical composition due to inertia, a crystal having a new chemical composition can be grown without being influenced by the old source gases. As a result, a sharp composition change can be achieved at the heterointerface. This means that the old source gases do not substantially remain in the quartz tube 65.

When the MQW 3 is formed through growth in a temperature range more than 550° C., the GaAsSb layer of the MQW considerably undergoes phase separation, leading to an increase in the density of the convex surface defects K. On the other hand, as described above, when a growth temperature of less than 400° C. is employed, the density of the convex surface defects can be decreased or made zero; however, carbon necessarily contained in source gases is incorporated into the epitaxial wafer. The incorporated carbon functions as a p-type impurity. Accordingly, the resultant semiconductor elements have poor performance and cannot be used as products.

As illustrated in FIG. 4, it is another point that the growth by metal-organic vapor phase epitaxy using only metal-organic sources is continued within the same growth chamber or the same quartz tube 65 from the formation of the MQW to the formation of the InP window layer 5.

Specifically, the epitaxial wafer 1a is not taken out from the growth chamber prior to the formation of the InP window layer 5 and the InP window layer 5 is not formed by another deposition method; accordingly, regrown interfaces are not formed. Since the InGaAs diffusive-concentration-distribution-adjusting layer 4 and the InP window layer 5 are continuously formed in the quartz tube 65, interfaces 16 and 17 are not regrown interfaces. In regrown interfaces, at least one of an oxygen concentration of 1×10¹⁷ cm⁻³ or more and a carbon concentration of 1×10¹⁷ cm⁻³ or more is satisfied; and the crystallinity becomes poor and the surface of the epitaxial layer structure is less likely to become smooth. In the present invention, both of the oxygen concentration and the carbon concentration are less than 1×10¹⁷ cm⁻³.

In the present embodiment, on the absorption layer 3 having a MQW, a non-doped InGaAs diffusive-concentration-distribution-adjusting layer 4 having a thickness of, for example, about 0.3 μm is formed. In the formation of photodetectors, diffusion of Zn at high concentration into the MQW results in degradation of the crystallinity. Accordingly, for the purpose of adjusting the diffusive concentration distribution of Zn, the InGaAs diffusive-concentration-distribution-adjusting layer 4 is formed. After the InP window layer 5 is formed, the p-type impurity Zn is selectively diffused by a selective diffusion method from the InP window layer 5 so as to reach the absorption layer 3 having a MQW. Although the InGaAs diffusive-concentration-distribution-adjusting layer 4 may be formed as described above, the formation thereof may be eliminated.

Even when the InGaAs diffusive-concentration-distribution-adjusting layer 4 is inserted and it is a non-doped layer, InGaAs has a narrow bandgap and hence the photodetectors can be made to have a low electric resistance. By decreasing the electric resistance, the responsivity can be enhanced and good device characteristics can be obtained.

While the epitaxial wafer 1a is left in the same quartz tube 65, on the InGaAs diffusive-concentration-distribution-adjusting layer 4, it is preferred that the undoped InP window layer 5 be successively epitaxially grown by metal-organic vapor phase epitaxy using only metal-organic sources so as to have a thickness of, for example, about 0.8 μm. As described above, the source gases are trimethylindium (TMIn) and tertiarybutylphosphine (TBP). By using these source gases, the growth temperature for the InP window layer 5 can be made 400° C. or more and 550° C. or less. As a result, GaAsSb of the MQW underlying the InP window layer 5 is subjected to no or relatively small thermal damage. Accordingly, the density of the convex surface defects K can be decreased to a practically allowable level and the carbon concentration can be decreased.

For example, growth of an InP window layer by molecular beam epitaxy (MBE) requires solid phosphorus source and hence has problems in terms of safety and the like; in addition, the production efficiency needs to be enhanced. In the case where the MQW 3 and the InGaAs diffusive-concentration-distribution-adjusting layer 4 are grown by MBE suitable for the growth of the MQW 3 and subsequently the InP window layer 5 is grown by a method other than MBE in view of safety, the interface 17 between the InGaAs diffusive-concentration-distribution-adjusting layer 4 and the InP window layer 5 is a regrown interface due to exposure to the air. The regrown interface can be identified through secondary ion mass spectrometry because it satisfies at least one of an oxygen concentration of 1×10¹⁷ cm⁻³ or more and a carbon concentration of 1×10¹⁷ cm⁻³ or more. The regrown interface forms a cross line through p-type regions; leakage current occurs in the cross line and device characteristics are considerably degraded.

Alternatively, for example, in the case of growth of an InP window layer not by metal-organic vapor phase epitaxy using only metal-organic sources but by metal-organic vapor phase epitaxy (MOVPE) simply employing phosphine (PH₃) as the phosphorus source, the decomposition temperature is high and hence the probability of thermally damaging the underlying GaAsSb is high.

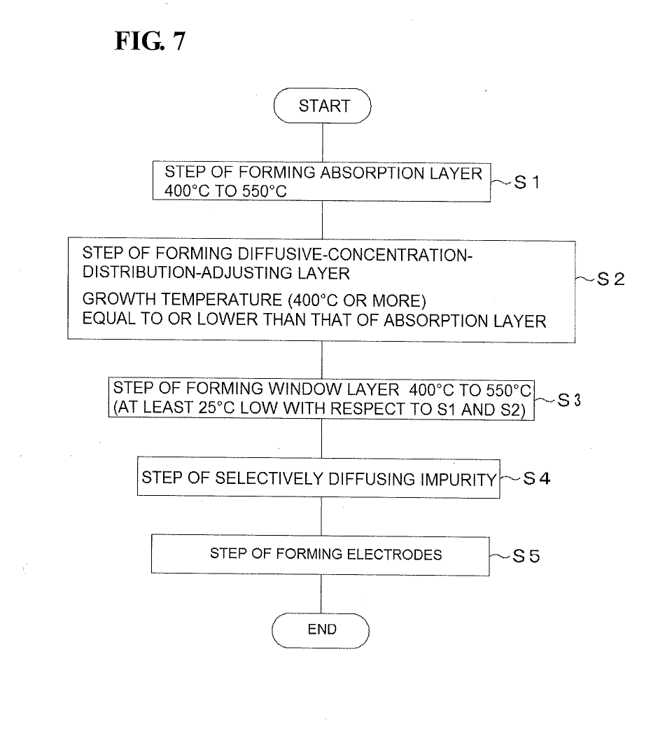

Epitaxial growth of layers of the photodetector illustrated in FIG. 1 has been described so far in detail. Hereinafter, the step of selectively diffusing a p-type impurity such as Zn and the step of forming the electrodes 11 and 12 will be described. FIG. 7 is a flow chart of a method for producing the photodetector 10 illustrated in FIG. 1. The steps S1 to S3 are the same as those described above. In particular, the growth temperature of the InGaAs diffusive-concentration-distribution-adjusting layer 4 is 400° C. or more and is preferably equal to or lower than the growth temperature of the absorption layer 3. This is because the RMS value can be easily adjusted to be in the range of 10 nm or more and 40 nm or less. Subsequently, in the steps S4 and S5, the pixels P are formed through selective diffusion of Zn and the electrodes are formed.

By selectively diffusing Zn serving as a p-type impurity through openings of the selective diffusion mask pattern 36 of a SiN film, p-type regions 6 extending from the InP window layer 5 through the InGaAs layer 4 to the absorption layer 3 are formed. The p-type regions 6 are separated by regions that are not subjected to the selective diffusion, and serve as main parts of the pixels P. By adjusting the pitch of openings of the selective diffusion mask pattern 36, such a p-type region 6 can be formed at a predetermined distance from the neighboring pixel or a side surface.

The p-electrodes 11 composed of AuZn are disposed so as to form ohmic contacts with the p-type regions 6. The n-electrodes 12 composed of AuGeNi are disposed so as to form ohmic contacts with exposed end portions of the upper surface of the InP buffer layer.

The InP substrate 1 may be an n-type conductive or semi-insulating substrate. Note that a structure in which the n-electrodes 12 are disposed on the back surface of the InP substrate 1 may be employed. In this case, the InP substrate 1 needs to be an n-type conductive substrate.

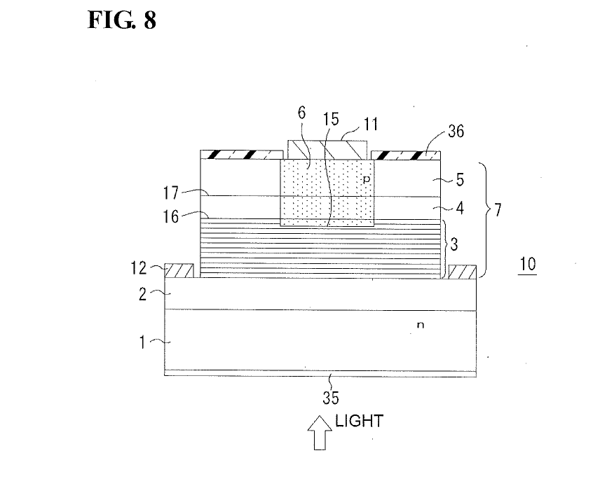

FIG. 1 illustrates a photodetector in which a plurality of pixels P are arranged. FIG. 8 illustrates a photodetector 10 having a single pixel. Such a photodetector is naturally embraced within the scope of the present invention. In Examples described below, the photodetector 10 in FIG. 8 was used for evaluations in terms of dark current and the like.

### EXAMPLES

Test samples satisfying the requirement that the surface of an InP window layer has an RMS value of 10 nm or more and 40 nm or less were prepared as invention examples, whereas test samples in which the RMS value is less than 10 nm were prepared as comparative examples. Photodetectors were produced from the test samples and measured in terms of dark current and sensitivity at a wavelength of 2 μm.

Properties of test samples ((1) substrate (the off angle is described in parentheses), (2) growth temperature of InGaAs diffusive-concentration-distribution-adjusting layer, (3) total thickness of InGaAs films, and (4) RMS value of surface of InP window layer)

### Invention Example A1

(1) just-angle substrate (0°), (2) 500° C., (3) 2.3 μm, (4) 23.4 nm

### Invention Example A2

(1) just-angle substrate (0.05°), (2) 500° C., (3) 2.3 μm, (4) 12.0 nm

### Invention Example A3

(1) just-angle substrate (−0.05°), (2) 500° C., (3) 2.3 μm, (4) 10.5 nm

### Invention Example A4

(1) just-angle substrate (0°), (2) 480° C., (3) 2.3 μm, (4) 29.5 nm

### Invention Example A5

(1) just-angle substrate (0°), (2) 460° C., (3) 2.3 μm, (4) 38.5 nm

### Invention Example A6

(1) just-angle substrate (0°), (2) 500° C., (3) 2.1 μm, (4) 12.0 nm

The RMS values in Invention examples A1 to A6 are in the range of 10.5 nm to 38.5 nm.

On the other hand, the RMS values in Comparative examples B1 to B4 are in the range of 7.5 nm to 9.5 nm, which are on the same level as the existing photodetectors.

### Comparative Example B1

(1) off-angle substrate (0.07°), (2) 500° C., (3) 2.3 μm, (4) 8.3 nm

### Comparative Example B2

(1) off-angle substrate (−0.07°), (2) 500° C., (3) 2.3 μm, (4) 7.5 nm

### Comparative Example B3

(1) just-angle substrate (0°), (2) 520° C., (3) 2.3 μm, (4) 9.5 nm

### Comparative Example B4

(1) off-angle substrate (0.07°), (2) 500° C., (3) 2.1 μm, (4) 8.0 nm

The photodetector illustrated in FIG. 8 was produced from each of the epitaxial wafers having the above-described properties. The photodetectors were measured in terms of dark current (213 K, −1.2 V) and sensitivity at a wavelength of 2 μm. The results are described in Table I.

TABLE I

| | Invention | Invention | Invention | Invention | Invention | Invention |
|---|---|---|---|---|---|---|
| | example A1 | example A2 | example A3 | example A4 | example A5 | example A6 |
| Off angle of substrate | 0 | 0.05 | −0.05 | 0 | 0 | 0 |
| Growth temperature | 500 | 500 | 500 | 500 | 500 | 500 |
| of absorption layer | | | | | | |
| (° C.) | | | | | | |
| Growth temperature of | 500 | 500 | 500 | 480 | 460 | 500 |
| diffusive-concentration- | | | | | | |
| distribution-adjusting layer (° C.) | | | | | | |
| Total thickness of | 2.3 | 2.3 | 2.3 | 2.3 | 2.3 | 2.1 |
| InGaAs films (μm) | | | | | | |
| RMS value | 23.4 | 12.0 | 10.5 | 29.5 | 38.5 | 12.0 |
| (nm) | | | | | | |
| Dark current (pA) | 3 | 5 | 5 | 1 | 5 | 5 |
| 213K, −1.2 V | Good | Good | Good | Good | Good | Good |
| Sensitivity | Good | Good | Goon | Good | Good | Usable |
| λ = 2 μm | | | | | | |

| | Comparative | Comparative | Comparative | Comparative |
|---|---|---|---|---|
| | example B1 | example B2 | example B3 | example B4 |
| Off angle of substrate | 0.07 | −0.07 | 0 | 0.07 |
| Growth temperature | 500 | 500 | 500 | 500 |
| of absorption layer | | | | |
| (° C.) | | | | |
| Growth temperature of | 500 | 500 | 520 | 500 |
| diffusive-concentration- | | | | |
| distribution-adjusting layer (° C.) | | | | |
| Total thickness of | 2.3 | 2.3 | 2.3 | 2.1 |
| InGaAs films (μm) | | | | |
| RMS value | 8.3 | 7.5 | 9.5 | 8.0 |
| (nm) | | | | |
| Dark current (pA) | 1000 | 1000 | 3000 | 5 |
| 213K, −1.2 V | Poor | Poor | Poor | Good |
| Sensitivity | Very poor | Very poor | Very poor | Poor |
| λ = 2 μm | Unmeasurable | Unmeasurable | Unmeasurable | |

Table I indicates that, in Invention example A4, the RMS value was 29.5 nm, the dark current was 1 pA, which was the best, and the sensitivity was good. The second-best dark current was 3 pA in Invention example A1 (RMS value: 23.4 nm). In the other Invention examples A2 (RMS value: 12.0 nm), A3 (RMS value: 10.5 nm), A5 (RMS value: 38.5 nm), and A6 (RMS value: 12.0 nm), the dark current was found to be an identical value of 5 pA. Thus, the minimum dark current is achieved when the RMS value is in the range of 20 nm to 30 nm. The sensitivity was also good except for Invention example A6 in which the total thickness of InGaAs films was a small value of 2.1 μm. Even in Invention example A6, the sensitivity was not very low.

In contrast, in Comparative examples B1 to B3 having an RMS value of less than 10 nm as with the existing photodetectors, the dark current was 1000 pA to 3000 pA, which is very poor. The sensitivity was also so poor that it was unmeasurable. Comparative example B4 provided better results than Comparative examples B1 to B3; however, compared with Invention examples A1 to A6, the characteristics (sensitivity) were obviously poor.

Embodiments of the present invention have been described so far. However, embodiments of the present invention disclosed above are given by way of illustration, and the scope of the present invention is not limited to these embodiments. The scope of the present invention is indicated by Claims and embraces all the modifications within the meaning and range of equivalency of the Claims.

### INDUSTRIAL APPLICABILITY

According to the present invention, the carrier concentration can be controlled with high accuracy and a photodetector having high sensitivity in the near-infrared region to the far-infrared region and having low dark current can be obtained. In this photodetector, the flatness of the surface of the window layer is not very high; however, this flatness is not so low that it becomes difficult to perform the subsequent production steps. This photodetector can be provided with high efficiency.

1. A photodetector comprising:
a substrate formed of a III-V compound semiconductor;
an absorption layer that is positioned on the substrate and configured to absorb light;
a window layer that is positioned on the absorption layer and has a larger bandgap energy than the absorption layer; and
a p-n junction positioned at least in the absorption layer,
wherein the window layer has a surface having a root-mean-square surface roughness of 10 nm or more and 40 nm or less.

2. The photodetector according to claim 1, wherein the p-n junction is formed by selective diffusion of an impurity through the window layer.

3. The photodetector according to claim 1, wherein the substrate has an off angle of −0.05° or more and +0.05° or less with respect to a (001) plane serving as a main surface of the substrate.

4. The photodetector according to claim 1, wherein the window layer contains phosphorus.

5. The photodetector according to claim 1, wherein the absorption layer includes a III-V compound semiconductor layer containing antimony.

6. The photodetector according to claim 1, wherein the window layer contains antimony as an impurity element.

7. The photodetector according to claim 1, wherein the absorption layer has a multiple-quantum well structure constituted by a pair of InₓGa₁₋ₓAs (0.38≦x≦1.00) and GaAs_{1-y}Sb_{y} (0.36≦y≦1.00) or a pair of Ga₁₋ᵤInᵤNᵥAs₁₋ᵥ (0.4≦u≦1.0, 0<v≦0.2) and GaAs_{1-w}Sb_{w} (0.36≦w≦1.00).

8. The photodetector according to claim 1, wherein the substrate is formed of any one of GaAs, GaP, GaSb, InP, InAs, InSb, AlSb, and AlAs.

9. The photodetector according to claim 1, comprising a diffusive-concentration-distribution-adjusting layer that is formed of a III-V compound semiconductor and is in contact with a surface of the absorption layer, the surface being on a side opposite to the substrate.

10. The photodetector according to claim 9, wherein the absorption layer contains InₓGa₁₋ₓAs (0.38≦x≦1.00), the diffusive-concentration-distribution-adjusting layer contains In_{z}Ga_{1-z}As (0.38≦z≦1.00), and a total film thickness of the InₓGa₁₋ₓAs and the In_{z}Ga_{1-z}As is 2.3 μm or more.

11. An epitaxial wafer comprising:
a substrate formed of a III-V compound semiconductor;
an absorption layer that is positioned on the substrate and configured to absorb light; and
a window layer that is positioned on the absorption layer and has a larger bandgap energy than the absorption layer,
wherein the window layer has a surface having a root-mean-square surface roughness of 10 nm or more and 40 nm or less.

12. The epitaxial wafer according to claim 11, comprising a p-n junction positioned at least in the absorption layer.

13. The epitaxial wafer according to claim 11 or 12, comprising a p-n junction formed by selective diffusion of an impurity through the window layer.

14. The epitaxial wafer according to claim 11, wherein the substrate has an off angle of −0.05° or more and +0.05° or less with respect to a (001) plane serving as a main surface of the substrate.

15. The epitaxial wafer according to claim 11, wherein the window layer contains phosphorus.

16. The epitaxial wafer according to claim 11, wherein the absorption layer includes a III-V compound semiconductor layer containing antimony.

17. The epitaxial wafer according to claim 11, wherein the window layer contains antimony as an impurity element.

18. The epitaxial wafer according to claim 11, wherein the absorption layer has a multiple-quantum well structure constituted by a pair of InₓGa₁₋ₓAs (0.38≦x≦1.00) and GaAs_{1-y}Sb_{y} (0.36≦y≦1.00) or a pair of Ga₁₋ᵤInᵤNᵥAs₁₋ᵥ (0.4≦u≦1.0, 0<v≦0.2) and GaAs_{1-w}Sb_{w} (0.36≦w≦1.00).

19. The epitaxial wafer according to claim 11, wherein the substrate is formed of any one of GaAs, GaP, GaSb, InP, InAs, InSb, AlSb, and AlAs.

20. The epitaxial wafer according to claim 11, comprising a diffusive-concentration-distribution-adjusting layer that is formed of a III-V compound semiconductor and is in contact with a surface of the absorption layer, the surface being on a side opposite to the substrate.

21. The epitaxial wafer according to claim 20, wherein the absorption layer contains InₓGa₁₋ₓAs (0.38≦x≦1.00), the diffusive-concentration-distribution-adjusting layer contains In_{z}Ga_{1-z}As (0.38≦z≦1.00), and a total film thickness of the InₓGa₁₋ₓAs and the In_{z}Ga_{1-z}As is 2.3 μm or more.

22. A method for producing an epitaxial wafer, comprising growing, by metal-organic vapor phase epitaxy using only metal-organic sources, at least the absorption layer and the window layer of the epitaxial wafer according to claim 11.

23. The method for producing an epitaxial wafer according to claim 22, wherein a diffusive-concentration-distribution-adjusting layer is grown on and in contact with the absorption layer such that a growth temperature of the diffusive-concentration-distribution-adjusting layer is equal to or lower than a growth temperature of the absorption layer.
